(19) United States
(12) Patent Application Publication
(10) Pub. No.: US 2007/0025895 A1
(43) Pub. Date: Feb. 1, 2007

(54) Protein crystallography dialysis chamber that enables off-site high throughput cocktail screen

(75) Inventor: Zunshe Qin, Palmerston North (NZ)

Correspondence Address: Zunshe Qin, 3 Burfield Place, Palmerston North, NZ

(73) Assignee: Zunshe Qin, Palmerston North (NZ)

(21) Appl. No.: 11/161,227

(22) Filed: Jul. 27, 2005

(51) Int. Cl. C30B 7/00; C30B 21/02; C30B 28/06; B01D 9/00

(52) U.S. Cl. 422/245.1; 117/68

(57) ABSTRACT

A device that enables protein materials dialyses against crystal mother liquid and methods for fabricating and using the device to screen crystallization cocktail solution are described herein. The device includes an open lumen attached by dialysis membrane at one end, which is immersed in the cocktail pool. In operation, a layer of liquid inert oil covers the protein material and prevents it evaporated in the crystallization process. The protein material loaded in the dialysis chamber may grow crystals through dialysis crystallization process.

### 1. FIELD OF THE INVENTION

The present invention relates in general to the biotechnology field and, in particular, to a protein crystallography dialysis devices and methods for identifying cocktail solution to grow protein crystal and more specifically, to devices and methods tailored to high throughput screen and methods for fabricating and using the protein crystallography dialysis devices.

### 2. DESCRIPTION OF RELATED ART

Following the completion of the sequence of the human genome, a crucial step in understanding living systems is determining the structure and function of the entire set of gene products. With mapping the 3-dimensional structure of proteins through X-ray crystallography, it becomes much easier to identify the leading compounds that might block target protein activity in the human body. Today, biochemical research associated with growing protein crystals and other biological crystals are carried out on a large scale in both industry and academia. It is desirable to have an apparatus that allows researchers to perform these studies in a convenient and inexpensive fashion.

Protein molecules in solution can pack into crystals at solvent conditions with selected ingredients through special crystallization process. The cocktail recipe for crystallization solutions might be discovered from unintentional experiments [Cudney, 1999]. Based on experiences and personal favor, the pre-compiled recipes [Uancarik, 1991], “sparse matrix sampling”, may also find its success in practice. To give crystallization a more rational appearance, partial factorial designs [Carter, 1997] may be an alternative to identify the cocktail recipe. In these designs, relative levels of important chemical factors are sampled to achieve good coverage and balance in the sampling.

The crystallization process is also crucial in growing protein crystals. Examples of these crystallization methods include the free interface diffusion method [Salemme, 1972], vapor diffusion in the hanging or sitting drop method [McPherson, 1982], batch method [Longley, 1967] and liquid dialysis [Bailey, 1940]. The individual proteins may require different super-saturation process for crystal nucleation and crystal growth. A crystallization strategy should include a variety of crystallization methods to maximize the chance for protein crystal growth [Weber, 1997].

Considerable number of trials may be involved to identify the proper cocktail formula and the crystallization process for a particular protein sample. A successful protein crystallization process is the product of the complexity of individual trial and the number of trials required for screening proper solution ingredients. As a result, growing protein crystals is a demanding task through the conventional strategies. Over years, the high throughput methods are developed, but limited to certain types of crystallization process.

The dialysis crystallization method is a classic and an important alternative to grow protein crystals. The dialysis process allows the protein material inside the dialysis chamber approaching the solvent composition defined by the crystallization cocktail pool. The dialysis method allows multiple cocktails to be tested against a particular protein material setup.

A typical trial of dialysis crystallization process utilizing the traditional dialysis chamber and method has several drawbacks, and practically not suitable for high throughput operation. The method is described in great detail below with reference to FIG. 1A-1E.

Referring to FIG. 1 (PRIOR ART), there are illustrated different views of one set of traditional dialysis button 101 designed to match the reservoirs 104, most likely in a 4*6 format plate 116. The reservoirs 104 are generally arranged in a matrix of mutually perpendicular rows and columns. The rims 112 of each reservoir are greased with vacuum oil 111. Each slip 105 is sized to fit over one of the reservoirs 104 in the plate 116. Referring to FIG. 1C, the dialysis chamber 102, in a volume of about 5 micro liters, is an indention on the top of the dialysis button 101. The U-shape gorge 115 on the low part of the dialysis button fixes the O-ring 107. The golf accessory 106 guides the O-ring 107 to gorge 115. The loaded O-ring 107 tightens up dialysis membrane 100.

Referring to FIG. 1A-1B, there is crystallization cocktail solution 113 in container 114, prepared by either the researcher or a vender. To examine merit of a particular cocktail solution, the researcher needs to pipette (110) a larger volume of cocktail 113 to the reservoir 104, ˜1 milliliter. The researcher may also need to pipette (109) a small volume of cocktail solution 113 (˜2 micro liters ) to the dialysis chamber 102, and mix with protein material 108 (˜2 micro liters ) loaded into the dialysis chamber 102. The golf accessory 106 is used to expand the rubber O-ring 107, allowing the O-ring slipping down to U-gorge 115 on the dialysis button. When dialysis membrane 100 is placed under the O-ring 107, loading O-ring onto the dialysis button seals the dialysis chamber 102. Referring to FIG. 1D, after the rim of reservoir 112 is greased with vacuum oil 111 and the fully assembled dialysis button 103 is submerged into crystallization cocktail 113, the reservoir 104 is sealed by the slip 105 to complete the dialysis crystallization experimental setup.

Accordingly, there is and has been a need for a cost effective and user-friendly dialysis process that can be used in high throughput mode to help a researcher perform protein crystallization studies. The dialysis chambers and the methods of the present invention satisfy this need and other needs.

Bailey, K. (1940) Nature 145:934-935

Carter, C. W. (1997), Methods in Enzymology 276, 74-99

Cudney, B. (1999), The Rigaku Journal. 16(1), 1-7

Jancarik, J. and Kim, S.-H. (1991), J. Appl. Cryst. 24, 409-411

Longley, W. (1967), J. Mol. Biol. 30, 323-327

McPherson, A. (1982) Preparation and Analysis of Protein Crystals, John Wiley and Son, New York, pp 82-127

Salemme, F. R. (1972) Arch. Biochem. Biophys. 151:533-539

Weber, P. C. (1997), Methods in Enzymology 276, 13-22

### 3. BRIEF DESCRIPTION OF THE INVENTION

Continuing to the priority provisional application, the present invention includes an open lumen as a dialysis chamber and the methods for fabricating and using the open lumen to screen cocktails. Distinguishing the present invention is the performance of the screen in substantially simplified procedure of dialysis method with high efficiency.

The devices in accordance with the present invention are also capable of transporting aliquots of assorted cocktail solutions. The present invention allows the dialysis crystallization screen to setup off-site and in high throughput mode.

The open lumen in the present invention is attached by dialysis membrane on one end, providing the dialysis interface. The other end is open, allowing easy addition of the protein material to the dialysis chamber. The dialysis chamber is completed by applying of the inert liquid oil to the open lumen. The module device holds aliquot of crystallization cocktail solution for transporting and is pre-assembled for addition of protein material, allowing minimum intervention during screen. A plurality of module devices enables parallel process to achieve high throughput screen off-site.

### 4. BRIEF DESCRIPTION OF THE DRAWINGS

A more complete understanding of the present invention may be had by reference to the following detailed description when taken in conjunction with the accompanying drawings wherein:

FIG. 1 (PRIOR ART) illustrates different views of one set of traditional dialysis chamber made by Hampton Research Corporation;

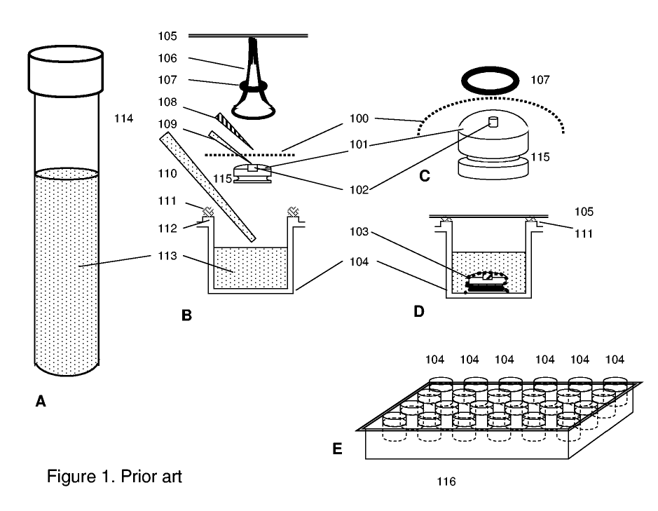

FIG. 2 (Open lumen) illustrates different views of dialysis device in accordance with the present invention;

FIG. 3 (Embodiment of open lumen) illustrates different views of one embodiment of the open lumen designed to fit into the circumstance, and the procedure of the experimental setup in accordance with the present invention;

FIG. 4 (Embodiment of integrated open lumen) illustrates different views of an integrated embodiment of the open lumen and the cocktail reservoir, and the procedure of the preferred methods for using an open lumen and a plural device to screen cocktails in high throughput mode in accordance with the present invention;

FIG. 5 (Embodiment of another open lumen) illustrates different views of another embodiment of the open lumen and the procedure of using an open lumen as well as plural device to screen cocktails in accordance with the present invention;

FIG. 6 (Embodiment of still another open lumen) illustrates different views of still another embodiment of the open lumen and the procedure of using an open lumen as well as plural devices to screen cocktails and using an array of open lumens to screen multiple array of assorted cocktails in accordance with the present invention;

### 5. DETAILED DESCRIPTION OF THE INVENTION

A “cocktail”, as the term is used herein, refers to a solution mixture comprising assorted ingredients, such as precipitants, solvent, pH buffer, salts, and additional additives, in defined composition. A “mother liquid” of a protein material is one of cocktail solutions, which fosters the protein material to grow crystals at elapse of time interval. The protein materials to be crystallized may be any substance capable of crystallizing or co-crystallizing. Exemplary protein materials include a virus, a protein, a peptide, a nucleoside, a nucleotide, ribonucleic acids, deoxyribonucleic acids, a ligand, a drug molecule, an additional a small molecules, or mixtures or composites of combinations thereof. An “assorted cocktail”, as the term is used herein, refers to an array of multiple cocktails, each is formulated distinguish according to composition of ingredients.

The “off-site application”, as the term is used herein, refers to a method, from which the crystallization screen devices are utilized in an application, which is different from the process of fabricating and assembling the screen devices. According to present invention, the process of screening crystallization cocktails contains two major stages: the cocktails may be aliquot and the screen devices may be pre-assembled away from the end researchers without inclusion of the protein material; and the protein materials might be included into the screen devices “on-spot ” during assembling the device or “off-site ” at a different place and time by the end user.

According to present invention, the crystallization devices provide an enclosed environment respectively within which crystallization attempts are performed; crystalline samples may be formed and analyzed. Crystallization attempts may be conducted in plurality of module devices.

One advantage provided by conducting crystallizations in pre-made array of the module dialysis devices is that it facilitates parallel screen of many cocktails through solo addition step of the protein material to the dialysis chambers.

A further advantage provided by performing crystallizations according to the present invention is a reduction in time requirement for setting up dialysis crystallizations. More specifically, the present invention reduces multiple steps of traditional dialysis crystallization methods into solo step.

Still a further advantage provided by performing crystallizations according to the present invention is the reduced requirement for the protein material to screen cocktail solutions. More specifically, the present invention allows a number of different sets of assorted cocktails to be screened against single set of protein sample.

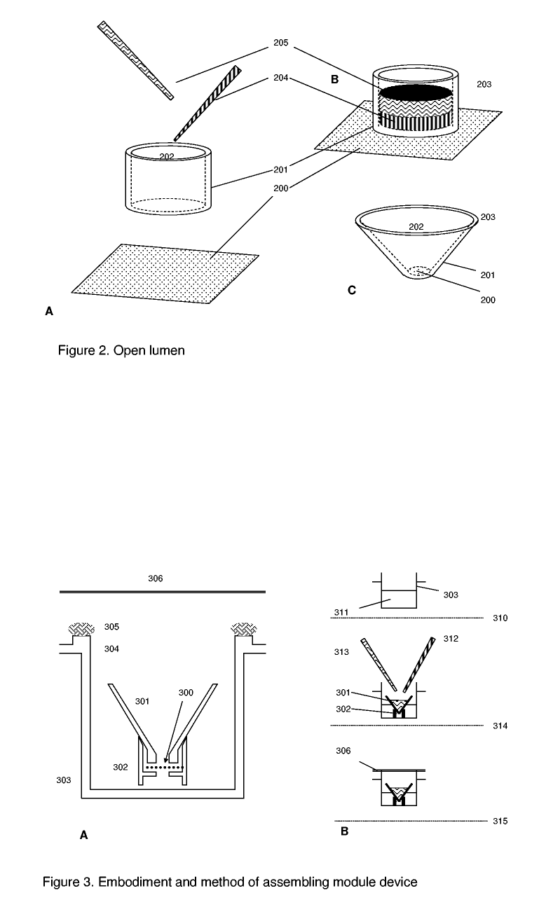

Referring to FIG. 2A, the dialysis chamber 202 the said is formed by an open lumen 201. The dialysis membrane 200 is attached to one end of the lumen, creating the dialysis chamber 202 with open end. The protein material 204 to be crystallized is added during screen stage. To prevent evaporation of the protein material, lightweight inert oil 205, such as paraffin oil, is applied to the lumen. The paraffin oil maybe applied into the open lumen before the addition of the protein materials. Referring to FIG. 2B, an illustrative presentation of the assembled dialysis chamber 203, one preferred embodiment of the lumen the said is perpendicular to liquid surface, and the membrane end of the lumen will be submerged in the cocktail solution.

Referring to FIG. 2C, the open lumen 201 the said may have a variety of cross sectional geometries. For example, the cross-sectional geometry of the chamber may be circular, semi-circular, ovoid, “U” shaped, “V” shaped, square, rectangular, or one or more combinations thereof. The open lumen the said might be any shape, once it holds the topological resemblance to the open lumen the said. The preferred embodiment of the open lumen 201 has a reversed conical shape or pyramid shape with the dialysis membrane 200 pointing down and establishing direct contact with the cocktail solution.

The open lumen may be formed in any substance. For applications where it is desired to have a disposable device, due to ease of manufacture and cost of materials, the device will typically be fabricated from a plastic. For ease of detection and fabrication, the entire device may be fabricated from a plastic material that is optically transparent, as that term is defined above. Particular plastics finding use include polypropanel, polymethylacrylate, polycarbonate, polyethylene, polystyrene, and the like. The lumen is preferably optically clear, transparent, allows for various spectroscopic analyses (e.g., Raman, UV/VIS, IR or x-ray spectroscopy, polarization, fluorescent, and with suitable designs, x-ray diffraction) to be performed in situ.

Referring to FIG. 2, the semi-permeable membrane 200 may be of any molecular weight cut-off known in the art. Exemplary molecular weight cut-offs of the membrane are 500 Daltons, 1,000 Daltons, 2,000 Daltons, 5,000 Daltons, 10,000 Daltons, 25,000 Daltons, 50,000 Daltons. Alternatively, the membrane may have a pore size from about 0.01 microns to about 0.1 micron. A preferred embodiment of the cut-off of the semi-permeable membrane is about 5,000 Daltons. The semi-permeable membrane is preferably optically transparent, and made from any material known in the art. Exemplary membrane materials include celluloses (e.g., regenerated celluloses), cellulose acetates, polysulfones, polytetrafluoroethylenes (e.g., TEFLON.RTM. by DuPont), nitrocelluloses, polycarbonates, polyamides, polyolefins (e.g., polypropylene, polyethylene, and mixtures thereof), polyvinylidenefluorides, and the like.

The dialysis membrane the said may be placed on the bottom of the open lumen by any physical or chemical method known in the art. Physical and chemical methods for placing the membrane include, for example, physical placement, adhesion, bonding, chemical attachment, and heat-based sealing. Physical placement may involve using all or part of the lumen to guide the membrane into place, and then physically locking the lumen into a basement using, for example, a press fit, a snap fit, a screw fit. Physical placement may optionally involve the use of a gasket. Adhesion may involve applying liquid and/or solid adhesives, such as cyanoacrylate, acrylic, urethane, epoxy or silicone, to the bottom of the lumen, lower lumen and/or membrane to secure the membrane into place. Adhesion may optionally also involve physical placement, such as the use of a gasket. Bonding may involve ultrasonically attaching the membrane to the lumen. Heat-based sealing may involve melt bonding the membrane to the lumen. All these methods may be applied alone or used in combination herein to place the membrane to proper position.

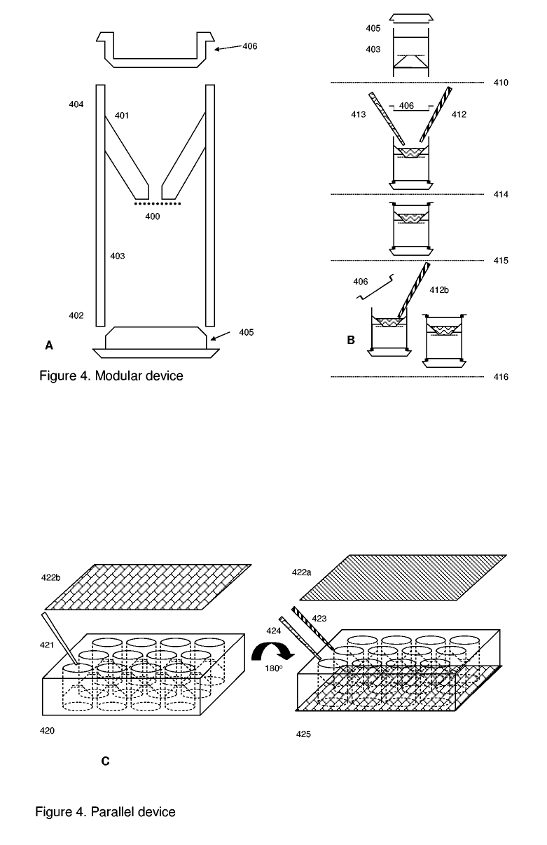

Referring to FIG. 3A, there is a preferred embodiment of modular dialysis crystallization device, and the procedure of the experimental setup in accordance with the present invention. The cocktail reservoir 303 is a container, which may be filled with one type of cocktail solution in application. The rim of reservoir 304 is greased with vacuum oil 305 or a like. A glass or plastic slip 306 seals the cocktail reservoir to form an enclosed crystallization environment. The dialysis membrane 300 attaches the open lumen 301. The completed dialysis chamber is placed over the supporter 302, allowing the free mass other than protein materials exchange through the dialysis membrane between the dialysis chamber and the reservoir.

Referring to FIG. 3B, there is a preferred dialysis crystallization procedure including steps 310, 314 and 315 in accordance with the present invention. The cocktail 311, prepared by either the end user or a vender, fills reservoir 303 at stag 310; At stag 314, a small volume of paraffin oil 313 (˜20 micro liters) may be pipetted into the open lumen 301, which is placed over a base 302, allowing the membrane end 300 of the lumen to be submerged into the cocktail solution 311; The protein material (˜2 micro liters) is loaded into the dialysis chamber 301 by pipette 312; After the reservoir 303 with cocktail 311 is sealed by the slip 306 at stag 315, the enclosed space allows potential dialysis crystallization process to occur.

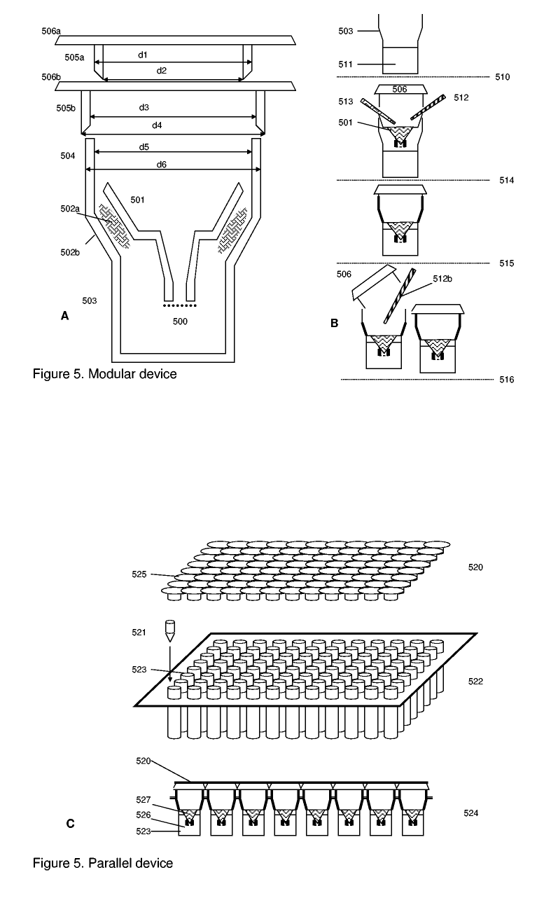

There is a preferred embodiment of integrated open lumen and the cocktail reservoir, in accordance with the present invention. Referring to FIG. 4A, the open lumen 401 the said is integrated to the cocktail reservoir 403. The lid 405 matches the rim 402 of the reservoir. The lid 406 matches the rim 404 of the integrated lumen.

Referring to FIG. 4B, there is a preferred dialysis crystallization procedure including steps 410, 414, 415 in accordance with the present invention. There is a crystallization cocktail 411 that is subjected to screen and prepared by either the researcher or a vender; The cocktail solution fills the integrated reservoir 403 at step 410; At step 414, the reservoir 403 is then sealed by lid 405, and rotates upside down, still allowing the membrane end of the lumen 400 to be immersed by the cocktail solution; A small volume of paraffin oil 413 or a like (˜20 micro liters) is added to the dialysis chamber, and the protein material 412 (˜2 micro liters) is loaded into the dialysis chamber; Following the open lumen is sealed by lid 406 at step 415, the enclosed space allows potential crystallization process to occur.

Still referring to FIG. 4B, there is still another application method with single step 416, in accordance with the present invention. The dialysis device is prepared without inclusion of protein material into the dialysis chamber, such that as the procedure illustrated on steps 410, 414 and 415. The end module device at step 415 contains a particular cocktail for screen. To accomplish the screen, the end user opens the reversible lid 406, applies the protein material 412b, and re-seals the module device. The enclosed environment enables the dialysis crystallization process.

Referring to 4C, there is a preferred method in accordance with the present invention. The integrated cocktail container and open lumen has been collectively fabricated into a plate 420, exemplary as, but not limited to 3*4 formats. After the container has been filled with assorted cocktails 421, respectively, the non-reversible lid 422b seals the cocktail containers collectively. Reversing the plate 420 allows the open lumens to be filled with the paraffin oil or the like 424. The assorted cocktails are screened against protein material 423, and then be sealed by reversible lid 422a for the dialysis crystallization process to occur. There is another preferred method in accordance with the present invention. The plate 420 is assembly into plate 425 without inclusion of protein material for crystallization process. The lid 422a is fabricated as reversible lid and is reopened for inclusion of protein material during off-site application.

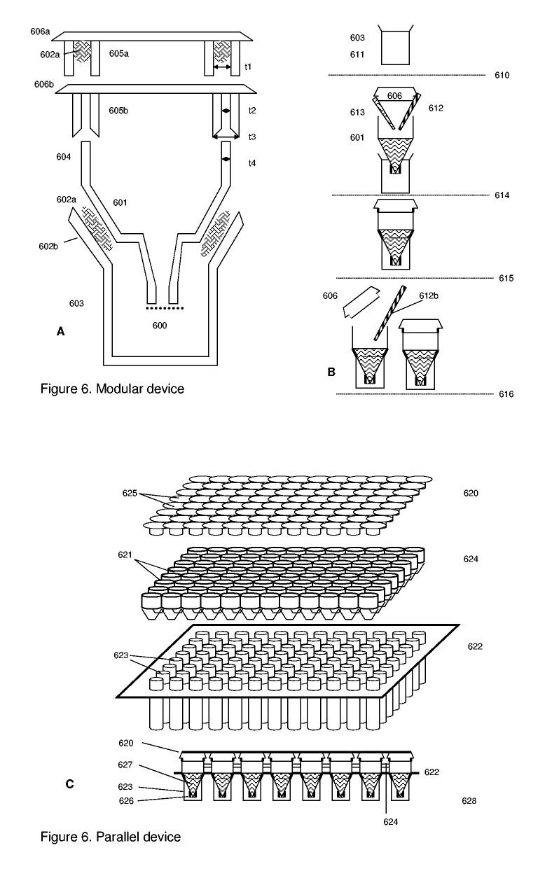

Referring to FIG. 5, there is another preferred embodiment of open lumen, and the procedure of using an open lumen as well as the plural device to screen cocktails in accordance with the present invention. The cocktail reservoir 503 is a container, which may be filled with one type of cocktail solution in application. One preferred embodiment of the open lumen 501 is attached with dialysis membrane 500, and embedded inside the cocktail reservoir 503 the said. The dialysis chamber may be filled with paraffin oil in application, and inserted directly into cocktail during crystallization screen stage. The vacuum oil or adhesive 502a may be applied on the step 502b on the wall of reservoir 503. The cocktail reservoir is sealed by reversible lid 506a or 506b.

One preferred embodiment of the reversible lid 506a has a chimney 505a projected downward. The outer diameter d1 of the projected chimney 505a over-fits the inner diameter d5 of the cocktail reservoir wall 504, allowing tight physical fit between the lid and the inner wall of the reservoir. Still another preferred feature for chimney 505a in accordance with the present invention is that the chimney is constructed with a leading diameter d2, which is smaller than the inner diameter d5 of the cocktail reservoir wall 504. The d2 is gradual increase to d1 of the chimney 505a, providing a guide during the physical press.

Still another preferred embodiment of the reversible lid 506b has a chimney 505b projected downward. The inner diameter d3 of the projected chimney 505b is smaller than the outer diameter d6 of the cocktail reservoir wall 504, allowing tight physical fit between the lid and the wall of the reservoir 504. Still another preferred feature for chimney 505b in accordance with the present invention is that the chimney is constructed with a leading diameter d4, which is wider than the outer diameter d6 of the cocktail reservoir wall 504. The d4 is gradual decrease to d3 of the chimney 505b, providing a guide during the physical press.

Referring to FIG. 5B, there is dialysis crystallization experiment procedure involving steps 510, 514, 515, in accordance with present invention. The cocktail solution 511 that is subjected to screen and prepared by either the researcher or cocktail vender, is filled to reservoir 503 at step 510; In the following step 514, a small volume of protein material (˜2 micro liters) 512 may be added to the dialysis chamber 501, which is filled with paraffin oil 513 or the like; The dialysis chamber is placed over the step 502b on the wall of reservoir 503, allowing the membrane end of the lumen 500 to be submerged into the cocktail solution 511; After applying the lid 506 to seal the reservoir 503 at step 515, the enclosed space enables the potential dialysis crystallization process to occur.

Referring to FIG. 5B, there is still another preferred embodiment of the dialysis crystallization experiment procedure for the off-site application in single step 516, in accordance with the invention. For off-site application, the dialysis lumen 501 may be glued to the reservoir 503, as illustrated in the FIG. 5A, without inclusion of protein material. The end module device at 515 contains a particular cocktail solution for screen. The cocktail screen procedure has been reduced for the end researcher: opening the reversible lid 506, applying the protein material 512b, and re-sealing the module device. The enclosed environment permits the dialysis crystallization process to occur.

Referring to FIG. 5C, there is a generalized use of an array of screen devices, exemplary by but not limited to 8*12 format, in accordance with the present invention. The individual lids 525 are molded onto the frame 520 to form plural lid, which matches the individual reservoirs 523 molded on the frame 522. The reservoirs are filled with assorted cocktail solutions subjected to screen. Each reservoir is inserted with an open lumen 521 as the dialysis chamber for a cocktail. The paraffin oil or a like 527 will be applied to the open lumens. The fully assembled devices are illustrated on 524. To screen the merit of the cocktail solutions means performing the crystallization experiment by using a protein material to be crystallized. The protein material may be a material to be crystallized that will undergo a dialysis experiment, wherein material will be transferred through dialysis. The protein material may be loaded to the open lumen manually or by an automatic dispenser before applying the plural lid 520 to cover the reservoirs individually. For off-site application, the reversible plural lid 520 seals the reservoirs without inclusion of the protein material. It is up to the end user to open the lids, and to include the protein material.

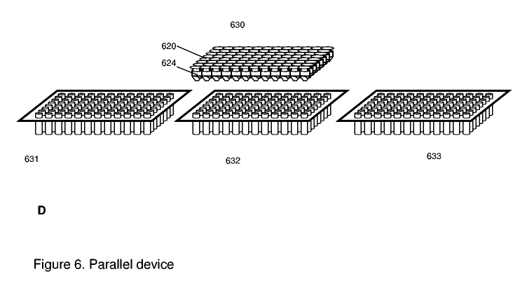

Referring to FIG. 6A, there is still another preferred embodiment of the screen device in accordance with the present invention. The open lumen 601 the said is complement to the cocktail reservoir 603 and serves as a cover to the cocktail reservoir, which may be filled with one type of cocktail solution in application. The lid 606a or 606b seals the open lumen 601 instead of the cocktail reservoir as illustrated in the previous embodiment. The dialysis chamber may be filled with paraffin oil, and topped directly onto the cocktail reservoir 603 during crystallization process. The vacuum oil or adhesive 602a may be applied on the step 602b on the wall of reservoir 603.

Referring to FIG. 6A, there is one preferred embodiment of the non-reversible lid 606a to seal the open lumen. The non-reversible lid 606a has double chimneys 605a projected downward. The gorge t1 between the chimneys is wider than the thickness t4 of the wall 604 of the open lumen. Vacuum oil 602a or the like is applied between the two chimneys to ensure the proper sealing of the open lumen 601.

Referring to FIG. 6A, there is another preferred embodiment of the reversible lid 606b to seal the open lumen. The reversible lid 606b has double chimneys 605b projected downward. The gorge t2 between the chimneys is narrower than the thickness t4 of the wall 604 of the open lumen, allowing tight physical fit between the lid and the wall 604 of the open lumen. The t3 is designed wider than t4 and is gradually decreased to t2 of the chimneys 605b, providing a guide during the physical press.

Referring to FIG. 6B, there is dialysis crystallization experiment procedure involving steps 610, 614 and 615, in accordance with present invention. The crystallization cocktail 611 that is subjected to screen and prepared by either the researcher or cocktail vender, is loaded to the reservoir 603 at step 610; In the following step 614, a small volume of protein material (˜2 micro liters) 612 may be added to the dialysis chamber 601, which is filled with the paraffin oil 613 or a like; The dialysis chamber 601 is placed over the cocktail reservoir 603 due to the step 602b on the wall of reservoir 603, allowing the membrane end of the lumen 600 to be immersed into the solution; The reservoir 603 with the cocktail solution 611 is sealed by the open lumen 601, which is consequently sealed by the lid 606a or 606b, at step 615. The enclosed environment enables the potential dialysis crystallization process to occur.

Referring to FIG. 6B, there is still another off-site application method, which is in accordance with the present invention. The protein material is not included into the dialysis chamber illustrated at step 614. The end module device contains a particular cocktail for screen. The cocktail screen procedure is reduced into solo step 616 for the end user: opening the reversible lid 606b, applying the protein material 412b, and re-sealing the module device. The enclosed environment permits the dialysis crystallization process to occur.

Still another generalized use of an array of screen devices, exemplary by but not limited to 8*12 formats, is illustrated in regard to FIG. 6C. The module lid 625, open lumen 621 and reservoir 623 are made collectively on frames 620, 624 and 622 respectively. As illustrated on the fully assembled plural device 628, the reservoirs are filled with assorted cocktail solutions subjected to screen, and the open lumens are filled with paraffin oil, and topped to the reservoir. The plural lid 620 may further cover the open lumen individually. The protein material may be loaded to the open lumen manually or by an automatic dispenser before applying the plural lid 620 to cover the open lumens. To screen the merit of the cocktail solutions means performing the crystallization experiment by using a protein material to be crystallized.

Referring to FIG. 6C, there is still another preferred method in accordance with the present invention. For off-site application, the reservoirs 624 are sealed by the reversible plural lid 620 without inclusion of the protein material. It is up to the end user to open the lid, and include the protein material.

Referring to FIG. 6D, there is still another preferred method in accordance with the present invention. The protein material is included inside the plural device 630, which is constructed by plural lid and open lumen filled with paraffin oil or a like. Several panels of assorted cocktail solutions, exemplary by 631, 632 and 633, are subjected to screen by topping device 630 on each panel separately in a pre-defined period. With this strategy, a great number of potential cocktail solutions can be screened by dialysis method with a reduced requirement of protein material.

Referring to FIG. 4A, 5A and 6A, there are disclosed in accordance with the present invention several embodiments of reversible and non-reversible lids. The reversible lid 506a and 506b are designed to match the outer or the inner wall of the cocktail reservoir 503 or the open lumen 601. The dual rims 605b are the intensified design of 505a and 505b and serve the same purpose. The 606a with the dual rims 605a and vacuum oil 602a is not for reversible use. The reversible lid and the reservoir together serve as a container of the cocktail solution aliquot during the transportation and storage for off-site application, and also provide an enclosed environment for the dialysis crystallization process occurring in the dialysis chamber.

Referring to FIGS. 5A and 6A, there are disclosed in accordance with the present invention an embodiment of supporting rim 502b or 602b on the reservoir respectively, allowing the dialysis membrane of the dialysis chamber to contact the cocktail properly. Still another preferred embodiment of the supporter in accordance with the present invention is the base accessory 302 illustrated on FIG. 3A.

Referring to FIGS. 4C, 5C, 6C and 6D, the invention provides cocktail screen dialysis systems in multi-well formats for the simultaneous screen of multiple cocktail recipes. The invention provides, but not limited to, plurality of module device in 12-well and 96-well formats. The single module device can be applied to examine the crystallization merit for one cocktail. For high throughput screen, module device may be molded into linear strip or planar plate. According to the relationship of the open lumen and the cocktail pool, the open lumen may be detached devices, or may be molded collectively onto a frame to form an array of open lumens. The prior arts of dialysis crystallization process evaluate a single test condition in each instance. By contrast, the present invention allows for multiple different crystallization conditions to be evaluated collectively.

The plural format of open lumens, cocktail reservoirs and the lids the said, may be manufactured by thermoplastic injection molding, punching, milling, any solid free form technology, such as three dimensional printing, or other types of manufacturing technologies for plastics, such as molding, embossing, laser drilling, extrusion, injection or electron deposition machining, for glass or silicon, conventional silicon processing technology, such as photolithography, deep reactive ion or wet etching, electron beam machining, micromachining, electro-discharge machining, reaction injection molding.

If a crystal grows, then the crystal may be examined in situ. Examination may be performed by any available method, including, but not limited to vision inspection. The crystal or crystallization mixture may be harvested from a particular device for further X-ray diffraction check out. The formula of the cocktail of the particular chamber and the related crystallization process will be applied to improve the crystal quality in further experiments.

Materials may be added to the devices of the present invention by a variety of different methods and mechanisms. A variety of commercial available liquid dispensers can deliver small volumes of material with the high degree of accuracy needed to repeatedly deliver the necessary drops into the open lumen for crystallization. For improved accuracy, multiple deliveries can be used to create the final, larger volume, from a series of smaller volumes.

A further feature of the use of a device employing centrifugal force is the ability to reposition the preload crystallization agents, which may be spilled on the wall during shipping for off-site application. This can be used to dramatically enhance the speed and efficiency of the crystallization setup. The centrifugal force causes liquids to flow within the enclosed devices according to the present invention. Through the use of centrifugal force, fluids dispersed during shipping can be repositioned to its zone. The use of centrifugal force is compatible with a wide variety of fluids. A particular advantage of the use of centrifugal force is the ability to set hundreds to thousands of replicate chambers in order simultaneously.

While the present invention is disclosed with reference to preferred embodiments and examples detailed above, it is to be understood that these examples are intended in an illustrative rather than limiting sense, as it is contemplated that modifications will readily occur to those skilled in the art, which modifications will be within the spirit of the invention and the scope of the appended claims. The patents, papers, and books cited in this application are to be incorporated herein in their entirety.

What is claimed is:

1. An article of crystallization ware for screen mother liquid by dialysis method, comprising at least:
(a) a mother liquid reservoir;
(b) an open lumen to hold a crystallization sample;
(c) the bottom side of said open lumen is attached by a dialysis membrane;
(d) the open side of said open lumen is covered by inert oil or a like;
(e) said dialysis membrane is coupled to the mother liquid of said mother liquid reservoir;
(f) said open lumen is sealed;
(g) said mother liquid reservoir is sealed.

2. A method of screening a set of cocktail solutions for mother liquid to grow crystal for a protein material in said crystallization ware according to claim 1, comprising steps of:
(a) loading said set of cocktail solution to a plural form of said mother liquid reservoir, respectively;
(b) coupling a plural form of said open lumen to said plural form of mother liquid reservoir;
(c) applying said protein material to said plural form of open lumen, respectively;
(d) applying said inert oil to said plural form of open lumen, respectively;
(e) sealing said mother liquid reservoir and said open lumen;
(f) and examining individual said open lumen to detect the crystallization sign of said protein material at an interval of time elapse.

3. A method of detecting a mother liquid off-site in high throughput mode from a set of cocktail solutions, comprising steps of:
(a) pre-assembling said set of cocktail solutions into a plural form of said crystallization ware with the open lumen sealed by a reversible or a disposable lid;
(b) shipping said pre-assembled crystallization ware off-site to a detection for said mother liquid being conducted;
(c) loading a target protein material into the open lumens of said crystallization ware through said reversible or disposable lid;
(d) and examining individual said open lumen to detect the crystallization sign of said target protein material at an interval of time elapse.
